(19) United States
(12) Patent Application Publication
(10) Pub. No.: US 2026/0182164 A1
(43) Pub. Date: Jun. 25, 2026

(54) Display Apparatus

(71) Applicant: LG Display Co., Ltd., Seoul (KR)

(72) Inventor: Yun-Jin Na, Paju-si (KR)

(21) Appl. No.: 19/324,539

(22) Filed: Sep. 10, 2025

(30) Foreign Application Priority Data
Dec. 23, 2024 (KR) 10-2024-0194023

(51) Int. Cl. H10K 59/124

(52) U.S. Cl. CPC H10K 59/124

(57) ABSTRACT

A display apparatus includes the substrate including the display area and the non-display area, the thin film transistor on the substrate, the light emitting device over the thin film transistor, wherein the substrate includes the first substrate, the second substrate on the first substrate, the intermediate insulating layer between the first substrate and the second substrate, and the intermediate insulating layer in the display area and the intermediate insulating layer in the non-display area may have different shapes.

### CROSS-REFERENCE TO RELATED APPLICATIONS

This application claims priority to Korean Patent Application No. 10-2024-0194023, filed in the Republic of Korea on Dec. 23, 2024, the entire contents of which is hereby expressly incorporated by reference into the present application.

### BACKGROUND

### FIELD OF THE INVENTION

This specification relates to a display apparatus.

### Description of the Related Art

As entering the information age, display apparatus that visually express information are rapidly developing, and in particular, the research is continuing on thinning, weight reduction, and low power consumption of display apparatus.

Examples of such display apparatuses include a liquid crystal display apparatus (LCD), an electro-wetting display apparatus (EWDs), and an organic light emitting display apparatus (OLED).

The organic light emitting display apparatus is a self-luminous display apparatus that do not require a separate light source, so that the lightweight and thin display apparatus can be fabricated. Furthermore, the organic light emitting display apparatus have advantages such as reduced power consumption due to low-voltage operation, excellent color reproduction, fast response times, wide viewing angles, and superior contrast ratios (CR). However, since the organic light emitting display apparatus are vulnerable to oxygen and moisture, the lifespan of the display apparatus may be reduced or the quality of the display apparatus may be deteriorated.

### BRIEF SUMMARY

Embodiments of the present specification provide a display apparatus in which a stacked structure of each layer in a substrate of a display panel is different for each region.

Embodiments of the present specification may provide the display apparatus capable of more effectively preventing a crack and/or a film lifting phenomenon between layers disposed on the substrate by disposing a coating layer including a hydrophobic material on the substrate.

A display apparatus according to an embodiment of the present specification includes a substrate including a display area and a non-display area, a thin film transistor on the substrate, a light emitting device over the thin film transistor, wherein the substrate includes a first substrate, a second substrate on the first substrate, an intermediate insulating layer between the first substrate and the second substrate, and the intermediate insulating layer in the display area and the intermediate insulating layer in the non-display area may have different shapes.

### BRIEF DESCRIPTION OF THE SEVERAL VIEWS OF THE DRAWINGS

FIG. 1 is a plan view of a display apparatus according to embodiments of the present specification.

FIG. 2 is a cross-sectional view of the display area according to embodiments of the present specification.

FIG. 3 is the cross-sectional view taken along the line A-A′ shown in FIG. 1.

FIG. 4 is the cross-sectional view taken along the line B-B′ shown in FIG. 1.

FIG. 5 is the cross-sectional view taken along the line C-C′ shown in FIG. 1.

FIGS. 6A and 6B are views illustrating another embodiment of the present specification.

FIGS. 7A to 7F are views illustrating a process of forming another embodiment of the present specification.

FIGS. 8A and 8B are views illustrating another embodiment of the present specification.

FIG. 9 is view illustrating another embodiment of the present specification.

FIG. 10 is view illustrating another embodiment of the present specification.

### DETAILED DESCRIPTION

Some embodiments of the present specification will be described in detail with reference to exemplary drawings. When adding reference numerals to components in each drawing, the same components may have the same numerals as much as possible even if they are shown in different drawings. In addition, when describing the present specification, if it is determined that a detailed description of a related known structure or function may obscure the gist of the present specification, the detailed description may be omitted. When “includes,” “has,” “consists of,” etc. are used in this specification, other parts may be added unless “only” is used. When a component is expressed in the singular, it may include a plurality unless there is a special explicit description.

In describing the components of the specification, terms such as first, second, A, B, (a), (b), etc. may be used. These terms are only for distinguishing the elements from other elements, and the essence, order, or number of the elements are not limited by the terms.

When it is described that a component is “connected” “coupled” or “connected” to another component, the component may be directly connected or connected to the other component, but indirectly without specifically stated It should be understood that other components may be “interposed” between each component that is connected or can be connected.

In describing a temporal relationship, for example, when a temporal predecessor relationship is described as being “after,” “subsequent,” “next to,” “prior to,” or the like, unless “immediately” or “directly” is not used, cases that are not continuous may also be included.

Meanwhile, when numerical values or corresponding information (e.g., levels, etc.) for components are mentioned, even without separate explicit description, the numerical values or corresponding information may be interpreted as including an error range that may occur due to various factors (e.g., process factors, internal or external impact, noise, etc.).

Hereinafter, various embodiments of the present specification will be described in detail with reference to the attached drawings.

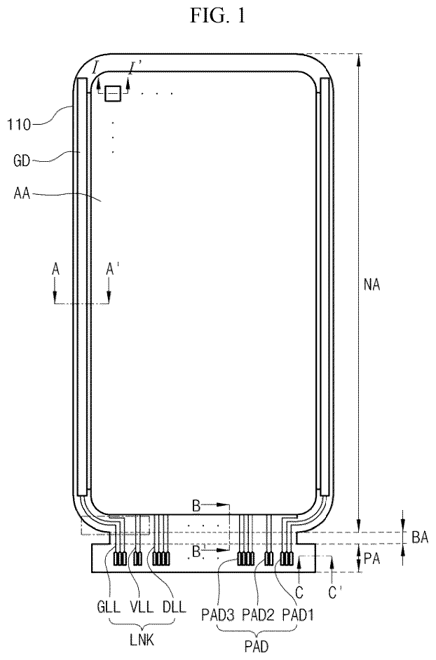

FIG. 1 is a plan view of a display apparatus according to embodiments of the present specification.

Referring to FIG. 1, the display apparatus 100 may include a substrate 101.

The substrate 101 can include a display area AA and a non-display area NA disposed outside the display area AA where a plurality of pixels are not disposed. The non-display area NA can be disposed adjacent to the display area AA but outside the display area AA.

The non-display area NA of the substrate 101 can include a peripheral area surrounding the display area AA, a bending area BA extending from one side of the peripheral area to be bent, and a pad area PA extending from the bending area BA.

The non-display area NA of the substrate 101 may be an area where various signal lines and circuits for driving sub-pixels disposed in the display area AA are disposed. For example, a gate driving unit GD, a data driving unit, a plurality of link lines LNK, and pads PAD may be disposed in the non-display area NA. The non-display area NA may be a bezel area. The non-display area NA may be the area extending from the display area AA, but is not limited thereto, and may also be the area surrounding the display area AA.

The pad PAD may include a plurality of first pads PAD1, a plurality of second pads PAD2, and a plurality of third pads PAD3. The plurality of first pads PAD1 may be disposed at both sides of the substrate 101 in the non-display area NA, and the plurality of second pads PAD2 may be disposed at the center of the substrate 101 in the non-display area NA. For example, the plurality of second pads PAD2 may be disposed between the plurality of first pads PAD1, and the plurality of third pads PAD3 may be disposed between the plurality of second pads PAD2.

The plurality of first pads PAD1 may be electrically connected to a plurality of gate link lines GLL among the plurality of link lines LNK. The plurality of gate link lines GLL may be connected to the gate driving unit GD.

The plurality of second pads PAD2 may be electrically connected to a plurality of power link lines VLL among the plurality of link lines LNK. The plurality of power link lines VLL may be connected to power line disposed in the display area AA.

The plurality of third pads PAD3 may be electrically connected to a plurality of data link lines DLL among the plurality of link lines LNK. The plurality of data link lines DLL may be connected to data lines disposed in the display area AA.

The gate driving unit GD may supply multiple scan signals to multiple scan lines according to multiple gate control signals from the timing controller. In FIG. 1, one gate driving unit GD is disposed in only one side of the substrate 101, but the number and arrangement of the gate driving unit GD are not limited thereto. For example, the plurality of gate driving units GD can be disposed at the both sides of the substrate 101 spaced apart from each other.

The substrate 101 is a base member for supporting various components of the display apparatus 100 and may include an insulating material. The substrate 101 may be made of a flexible material. For example, the substrate 101 may be made of a plastic material such as polyimide PI. The substrate 101 may be formed of a single layer or multiple layers. For example, the substrate 101 may include a plurality of polyimides PI and an intermediate insulating layer between the polyimides PI. The intermediate insulating layer may be made of silicon oxide (SiOx). For example, the substrate 101 may be formed of a triple layer of PI/SiOx/PI.

The substrate 101 may have an irregular shaped corner region. For example, a portion of the non-display area NA of the substrate 101 may be bent toward the rear surface of the display apparatus 100, and one edge of the substrate 101 may be bent toward the rear surface of the display apparatus 100 to have a predetermined curvature. The outermost region of the substrate 101 may be a trimming line.

The display area AA may have the shape corresponding to the irregular corner area of the substrate 101. The corners of the substrate 101 and the display area AA may be formed in a round shape. However, the present invention is not limited thereto, and the shapes of the substrate 101 and the display area (AA) may be formed various shapes suitable for the design of an electronic device equipped with the display apparatus 100.

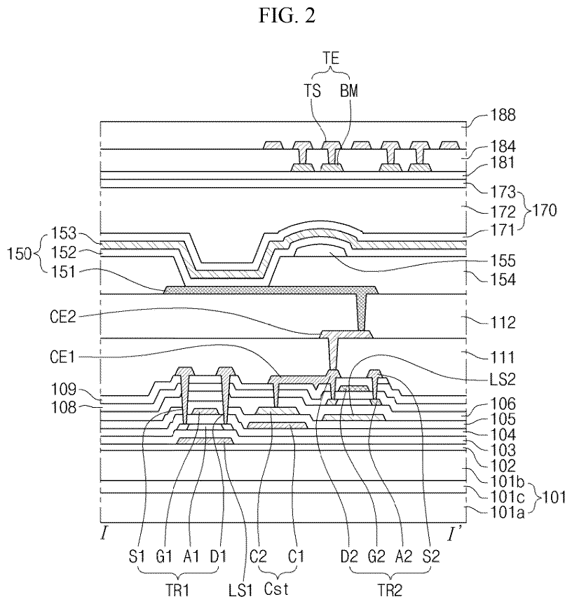

FIG. 2 is a cross-sectional view of a display area according to embodiments of the present specification.

Referring to FIGS. 1 and 2, the display apparatus 100 according to one embodiment of the present specification may include the substrate 101, a first lower buffer layer 102, a first upper buffer layer 103, a first thin film transistor TR1, a second thin film transistor TR2, a first gate insulating layer 104, a first interlayer insulating layer 105, a second buffer layer 106, a second gate insulating layer 108, a second interlayer insulating layer 109, a first connection electrode CE1, a first light shielding layer LS1, a first planarization layer 111, a second planarization layer 112, a second connection electrode CE2, a bank 154, a spacer 155, a light emitting device 150, an encapsulation portion 170, and a touch sensing unit.

The substrate 101 supports and protects the components of the display apparatus (100 thereon.

The substrate 101 may be made of an insulating material. The substrate 101 may include a first substrate 101a, a second substrate 101b, and an intermediate insulating layer 101c. The intermediate insulating layer 101c may be disposed between the first substrate 101a and the second substrate 101b. Sine the substrate 101 includes the first substrate 101a, the second substrate 101b, and the intermediate insulating layer 101c, the moisture infiltration can be prevented. For example, the first substrate 101a and the second substrate 101b may be made of the polyimide (PI), and the intermediate insulating layer 101c may be formed of the single layer of silicon nitride (SiNx) or silicon oxide (SiOx), or multiple layers thereof. The intermediate insulating layer 101c may not be formed in the partial area. For example, the intermediate insulating layer 101c may not be formed in a portion of the bending area BA shown in FIG. 1. For example, at least a portion of the bending area BA may be directly contact with the first substrate 101a and the second substrate 101b.

The first lower buffer layer 102 and the first upper buffer layer 103 may be disposed on the substrate 101. The first lower buffer layer 102 and the first upper buffer layer 103 may be disposed below the first thin film transistor TR1 to delay the diffusion of the moisture or the oxygen penetrated into the substrate 101 to the first thin film transistor TR1.

For example, the first lower buffer layer 102 and the first upper buffer layer 103 may be formed of the single layer of any one of amorphous silicon (a-Si), silicon nitride (SiNx), and silicon oxide (SiOx) or the multilayer thereof, but are not limited thereto.

The first thin film transistor TR1 may be disposed on the first upper buffer layer 103. The first thin film transistor TR1 may include a first active layer A1, a first gate electrode G1, a first source electrode S1, and a first drain electrode D1. Here, according to the design of the pixel circuit, the first source electrode D1 may become the first drain electrode, and the first drain electrode D1 may become the first source electrode.

The first active layer A1 may be disposed on the first upper buffer layer 103 to overlap with the first light-shielding layer LS1. The first active layer A1 may include amorphous silicon or poly-crystalline silicon.

For example, the first active layer A1 may include low-temperature polysilicon LTPS. Since the polysilicon has high mobility (over 100 cm²/Vs), low energy consumption, and excellent reliability, the polysilicon can be applied to a multiplexer (MUX) or/and the gate driving unit for driving thin film transistors of the display apparatus. In the display apparatus 100 according to one embodiment of the present specification, the polysilicon can be applied as the active layer A1 of the driving thin film transistor, but is not limited thereto.

The polysilicon can also be used as the active layer A2 of the switching thin film transistor, depending on the characteristics of the display apparatus 100. The polysilicon is formed by depositing an amorphous silicon (a-Si) material on the first upper buffer layer 103 and then dehydrogenating and crystallizing the deposited amorphous silicon. By patterning this polysilicon, the first active layer A1 may be formed. The first active layer A1 may include a first channel region which is formed when the first thin film transistor TR1 is driven, and first source and drain regions on both sides of the first channel region. The first source region refers to the portion of the first active layer A1 connected to the first source electrode S1, and the first drain region refers to the portion of the first active layer A1 connected to the first drain electrode D1. For example, the first source region and the first drain region may be formed by doping ions (impurities) into the first active layer A1. The first source region and the first drain region may be formed by doping the ions into the polysilicon material, and the first channel region may refer to a portion that is not ion doped and remains as a polysilicon material. The first channel region is the region that is not ion doped and is left as polysilicon material.

The first gate insulating layer 104 may be disposed on the first active layer A1. The first gate insulating layer 104 may be formed of the single layer of silicon nitride (SiNx) or silicon oxide (SiOx), or the multiple layers thereof. Contact holes are formed in the first gate insulating layer 104, so that the first source electrode S1 and the first drain electrode D1 are respectively connected to the first source region and the first drain region of the first active layer A1, respectively.

The first gate electrode G1 of the first thin film transistor TR1 and the first capacitor electrode C1 of the storage capacitor Cst may be disposed on a first gate insulating layer 104.

The first gate electrode G1 and the first capacitor electrode C1 may be formed in the single layer or the multiple layers made of one or an alloy of molybdenum (Mo), copper (Cu), titanium (Ti), aluminum (Al), chromium (Cr), gold (Au), nickel (Ni), and neodymium (Nd). The first gate electrode G1 may be formed on the first gate insulating layer 104 so as to overlap with the first channel region of the first active layer A1.

The first capacitor electrode C1 may be omitted depending on the operating characteristics of the display apparatus 100 and the structure and type of the thin film transistor. The first gate electrode G1 and the first capacitor electrode C1 may be formed by the same process. Furthermore, the first gate electrode G1 and the first capacitor electrode C1 may be formed of the same material on the same layer.

A first interlayer insulating layer 105 may be disposed on the first gate insulating layer 104, the first gate electrode G1, and the first capacitor electrode (C1). The first interlayer insulating layer 105 may be formed of the single layer of silicon nitride (SiNx) or silicon oxide (SiOx) or the multiple layers thereof. Further, a contact hole may be formed in the first interlayer insulating layer 105 to expose the first source region and the first drain region of the first active layer A1 of the first thin film transistor TR1.

The second capacitor electrode C2 of the storage capacitor Cst may be disposed on the first interlayer insulating layer 105. The second capacitor electrode C2 may be formed of the single layer or the multiple layers made of any one of molybdenum (Mo), copper (Cu), titanium (Ti), aluminum (Al), chromium (Cr), gold (Au), nickel (Ni), and neodymium (Nd), or an alloy thereof. The second capacitor electrode C2 may be formed on the first interlayer insulating layer 105 so as to overlap the first capacitor electrode C1. Further, the second capacitor electrode C2 may be made of the same material as the first capacitor electrode C1. The second capacitor electrode C2 may be omitted according to the driving characteristics of the display apparatus 100 and the structure and type of the thin film transistor.

A second buffer layer 106 may be disposed on the first interlayer insulating layer 105 and the second capacitor electrode C2. The second buffer layer 106 may be formed of the single layer of silicon nitride (SiNx) or silicon oxide (SiOx) or the multiple layers thereof. The contact hole may be formed in the second buffer layer 106 to expose the first source region and the first drain region of the first active layer A1 of the first thin film transistor TR1. Further, the contact hole may be formed in the second buffer layer 106 to expose the second capacitor electrode C2 of the storage capacitor Cst.

The second buffer layer 106 may be formed of the multi layers, but is not limited thereto.

A second active layer A2 of the second thin film transistor TR2 may be disposed on the second buffer layer 106. Here, the second thin film transistor TR2 may include the second active layer A2, a second gate insulating layer 108, a second gate electrode G2, a second source electrode S2, and a second drain electrode D2. Depending on the design of the pixel circuit, the second source electrode S2 may be the drain electrode, and the second drain electrode D2 may be the source electrode.

Further, the second active layer A2 may include a second channel region in which a channel is formed when the second thin film transistor TR2 is driven, a second source and drain regions in both sides of the second channel region. The second source region may be the portion of the second active layer A2 connected to the second source electrode S2, and the second drain region may be the portion of the second active layer A2 connected to the second drain electrode D2.

The second active layer A2 may be made of the oxide semiconductor. Since the band gap of the oxide semiconductor materials is wider than that of the silicon, the electrons cannot cross the band gap in the off state and thus the off-current is low. Accordingly, thin film transistors made of the oxide semiconductors may be suitable for switching thin film transistors having short on-times and long off-times characteristics, but are not limited thereto. That is, depending on the characteristics of the display apparatus 100, the oxide semiconductor may also be applied to driving thin film transistors. Furthermore, since the oxide semiconductor has low off-currents, the auxiliary capacitance is decreased and thus the oxide semiconductor is suitable for high-resolution display apparatus. For example, the second active layer A2 may be made of various metal oxides such as IGZO (indium-gallium-zinc-oxide), IZO (indium-zinc-oxide), IGTO (indium-gallium-tin-oxide), or IGO (indium-gallium-oxide).

The second active layer A2 can be formed by depositing the metal oxide on the second buffer layer 106, heat-treating for stabilization, and then patterning the metal oxide.

The second gate insulating layer 108 may be formed in the entire area of the substrate 101 including the second active layer A2. For example, the second gate insulating layer 108 may be formed of the single layer of silicon nitride (SiNx) or silicon oxide (SiOx) or the multiple layers thereof.

A second gate electrode G2 may be disposed on the second gate insulating layer (108).

The second gate electrode G2 may be formed of the single layer or the multiple layers made of one or an alloy of molybdenum (Mo), copper (Cu), titanium (Ti), aluminum (Al), chromium (Cr), gold (Au), nickel (Ni), and neodymium (Nd).

For example, the metal is formed on the second gate insulating layer 108, a photoresist pattern is formed on the metal, and then the metal is wet-etched using the photoresist pattern as a mask to form the second gate electrode G2. The wet etchant for etching the metal selectively etches molybdenum (Mo), copper (Cu), titanium (Ti), aluminum (Al), chromium (Cr), gold (Au), nickel (Ni), and neodymium (Nd) or their alloys thereof, and does not etch an insulating material.

A second interlayer insulating layer 109 can be disposed on the second gate insulating layer 108 and the second gate electrode G2.

The second interlayer insulating layer 109 may be formed of the single layer of silicon nitride (SiNx) or silicon oxide (SiOx) or the multiple layers thereof.

The first connection electrode CE1, the first source electrode S1 and a second drain electrode D1 of the first thin film transistor TR1, and the second source electrode S2 and the second drain electrode D2 of the second thin film transistor TR2 may be disposed on the second interlayer insulating layer 109.

The first connection electrode CE1 may be electrically connected to the second drain electrode D2 of the second thin-film transistor TR2. The first connection electrode CE1 can be electrically connected to the second capacitor electrode C2 of the storage capacitor Cst through the contact hole formed in the second buffer layer 106 and the second interlayer insulating layer 109. That is, the first connection electrode CE1 can electrically connect the second capacitor electrode C2 of the storage capacitor Cst and the second drain electrode D2 of the second thin film transistor TR2.

The first connection electrode CE1, the first source electrode S1 and the first drain electrode D1 of the first thin film transistor TR1, and the second source electrode S2 and the second drain electrode D2 of the second thin film transistor TR2 can be made of the same material by the same process.

For example, the first connection electrode CE1, the first source electrode S1 and the first drain electrode D1 of the first thin film transistor TR1, and the second source electrode S2 and the second drain electrode D2 of the second thin film transistor TR2 may be formed of the single layer or the multiple layers made of any one of molybdenum (Mo), copper (Cu), titanium (Ti), aluminum (Al), chromium (Cr), gold (Au), nickel (Ni), and neodymium (Nd), or the alloy thereof. For example, the first connection electrode CE1, the first source electrode S1 and the first drain electrode D1 of the first thin film transistor TR1, and the second source electrode S2 and the second drain electrode D2 of the second thin film transistor TR2 may be formed of a three layer structure of titanium (Ti)/aluminum (Al)/titanium (Ti), but is not limited thereto.

The first connection electrode CE1 may be formed integrally with the second drain electrode D2 of the second thin film transistor TR2, but is not limited thereto.

The second light shielding layer LS2 may be disposed below the second thin film transistors TR2. The second light-shielding layer (LS2) may be overlapped with the second active layer A2.

The light shielding layers LS1 and LS2 are made of the metal having low light transmittance to reflect the light incident into the first active layer A1 and the second active layer A2 from below. The light shielding layers LS1 and LS2 block the light incident into the first active layer A1 and the second active layer A2, and can protect the first active layer A1 and the second active layer A2.

For example, the light shielding layers LS1 and LS2 may be referred to a bottom shield metal (BSM), but is not limited thereto. The light shielding layers LS1 and LS2 may be formed of the single layer or the multiple layers made of one of, molybdenum (Mo), copper (Cu), titanium (Ti), aluminum (Al), chromium (Cr), gold (Au), nickel (Ni), and neodymium (Nd) or the alloy thereof, but is not limited thereto.

The first planarization layer 111 may be disposed on the first electrode CE1, the first source electrode S1 and the first drain electrode D1 of the first thin film transistor TR1, the second source electrode S2 and the second drain electrode D2 of the second thin film transistor TR2, and the second interlayer insulating layer 109.

The first planarization layer 111 may be an organic layer for planarizing and protecting the upper portion of the first thin film transistor TR1 and the second thin film transistor TR2. For example, the first planarization layer 111 may be made of the organic material such as an acrylic resin, an epoxy resin, a phenolic resin, a polyamide resin, or a polyimide resin.

The second connection electrode CE2 may be disposed on the first planarization layer 111. The second connection electrode CE2 may be connected to the second drain electrode D2 of the second thin film transistor TR2 through the contact hole formed in the first planarization layer 111. The second connection electrode CE2 may electrically connect the second thin film transistor TR2 to the anode electrode. The second connection electrode CE2 may be formed of the single layer or the multiple layers made of any one of molybdenum (Mo), copper (Cu), titanium (Ti), aluminum (Al), chromium (Cr), gold (Au), nickel (Ni), and neodymium (Nd), or the alloy thereof.

The second planarization layer 112 may be disposed on the second connection electrode CE2 and the first planarization layer 111. For example, the second planarization layer 112 may be made of the organic material such as the acrylic resin, the epoxy resin, the phenolic resin, the polyamide resin, and the polyimide resin.

A light emitting device 150 may be disposed on the second flattening layer 112. The light emitting device 150 may include the anode electrode 151, the light emitting layer 152, and the cathode electrode 153.

The anode electrode 151 may be disposed on the second planarization layer 112. The anode electrode 151 may be electrically connected to the second connection electrode CE2 through the contact hole formed in the second planarization layer 112. The anode electrode 151 may be made of the metal.

If the display apparatus 100 is a top emission type, in which the light from the light emitting device 150 is emitted from the top side of the display apparatus, the anode electrode 151 may further include a transparent conductive layer and a reflective layer on the transparent conductive layer. For example, the transparent conductive layer may be made of the transparent conductive oxide, such as indium tin oxide (ITO) or indium zinc oxide (IZO). The reflective layer may be made of silver (Ag), aluminum (Al), gold (Au), molybdenum (Mo), tungsten (W), chromium (Cr), or the alloy thereof, but is not limited thereto. The anode electrode 151 is disposed to correspond to each of the plurality of sub-pixels. The anode electrode 151 may be disposed on the second planarization layer 112.

The bank 154 may be disposed on the anode electrode 151. The bank 154 may be disposed to cover the end of the anode electrode 151. An open unit corresponding to the light emitting area of the sub-pixel is formed in the bank 154, so that a part of the anode electrode 151 may be exposed through the open unit. The bank 154 may be made of the inorganic insulating material such as silicon nitride (SiNx) or silicon oxide (SiOx) or the organic insulating material such as a benzocyclobutene-based resin, an acrylic resin, or an imide-based resin, but is not limited thereto.

The spacer 155 may be disposed on the bank 154. The spacer 155 may be made of the same material as the bank 154. The spacer 155 protects the light emitting device 150 from the damage caused by a fine metal mask (FMM) used for patterning the light emitting layer 152.

The light emitting layer 152 is disposed on the anode electrode 151 and the bank 154. The light emitting layer 152 may be disposed on the open unit of the bank 154 and the upper surface of the bank 154. Accordingly, the light emitting layer 152 may be disposed on the anode electrode 151 exposed through the open unit of the bank 154.

The light emitting layer 152 may include multiple organic layers. For example, the light emitting layer 152 may include the organic layers such as a hole injection layer, a hole transport layer, an electron transport layer, and an electron injection layer. Meanwhile, if the light emitting layer 152 emits white light, the light emitted from the light emitting layer 152 may be converted into light of various colors by the multiple color filters, but is not limited thereto.

At least a portion of the light emitting layer 152 may be partitioned by a bank 154.

The cathode electrode 153 may be disposed on the light emitting layer 152. Since the cathode electrode 153 supplies electrons to the light emitting layer 152, Since the cathode electrode 153 is made of the conductive material having a low work function. The cathode electrode 153 may be formed of the single layer across a plurality of sub-pixels. That is, the cathode electrodes 153 of each of the plurality of sub-pixels may be connected to each other to form a single integrated electrode.

For example, the cathode electrode 153 may be formed of the transparent conductive material such as indium tin oxide (ITO), indium zinc oxide (IZO), or an ytterbium (Yb) alloy. The cathode electrode 153 may further include the metal doping layer, but is not limited thereto.

The encapsulation unit 170 may be disposed on the light emitting device 150. The encapsulation unit 170 may be formed of the single layer structure or the multilayer. For example, the encapsulation unit 170 may include a first inorganic encapsulation layer 171, an organic encapsulation layer 172 on the first inorganic encapsulation layer 171, and a second inorganic encapsulation layer 173 on the organic encapsulation layer 172.

At this time, the first inorganic encapsulation layer 171 and the second inorganic encapsulation layer 173 are made of the inorganic material, and the organic encapsulation layer 172 is made of the organic layer. Among the first inorganic encapsulation layer 171, the organic encapsulation layer 172, and the second inorganic encapsulation layer 173, the organic encapsulation layer 172 is the thickest to function as the planarization layer.

The first inorganic encapsulation layer 171 may be disposed on the cathode electrode 153 and thus may be disposed closest to the light emitting device 150. The first inorganic encapsulation layer 171 may be made of the inorganic insulating material capable of low-temperature deposition. For example, the first inorganic encapsulation layer 171 may be made of silicon nitride (SiNx), silicon oxide (SiOx), silicon oxynitride (SiON), or aluminum oxide (Al2O3). Since the first inorganic encapsulation layer 171 is deposited in a low-temperature atmosphere, the light emitting layer 152 including the organic material vulnerable to high temperatures can be prevented from being damaged during the deposition process.

The organic encapsulation layer 172 may be formed with a smaller area than the first inorganic encapsulation layer 171. In this case, both ends of the first inorganic encapsulation layer 171 are exposed. The organic encapsulation layer 172 may alleviate stress between layers due to bending of the display apparatus and enhance the degree of the planarization.

For example, the organic encapsulation layer 172 may be made of the organic insulating material such as acrylic resin, epoxy resin, polyimide, polyethylene, or silicon oxycarbon (SiOC). For example, the organic encapsulation layer 172 may be formed with an inkjet method, but is not limited thereto.

The second inorganic encapsulation layer 173 may be formed to cover the upper and side surfaces of the organic encapsulation layer 172 and the first inorganic encapsulation layer 171, respectively. At this time, the second inorganic encapsulation layer 173 can minimize or block the external moisture or oxygen into the first inorganic encapsulation layer 171 and the organic encapsulation layer 172. For example, the second inorganic encapsulation layer 173 may be made of the inorganic insulating material such as silicon nitride (SiNx), silicon oxide (SiOx), silicon oxynitride (SiON), or aluminum oxide (Al2O3).

A touch sensing unit may be disposed on the encapsulation unit 170. The touch sensing unit may include a touch electrode TE having a touch sensor metal TS and a bridge metal BM, a touch buffer layer 181, a touch interlayer insulating layer 184, and a touch planarization layer 188.

For example, the touch buffer layer 181 may be disposed on the second inorganic encapsulation layer 173, and the touch electrode TE may be disposed on the touch buffer layer 181.

The touch electrode TE may include the touch sensor metal TS and the bridge metal BM. The touch interlayer insulating layer 184 may be disposed between the touch sensor metal TS and the bridge metal BM.

The touch buffer layer 181 and the touch interlayer insulating layer 184 may be disposed to eliminate any steps in the area where the touch electrode TE is disposed and ensure good electrical insulation. Accordingly, the touch buffer layer 181 and the touch interlayer insulating layer 184 may be made of the inorganic material. For example, the touch buffer layer 181 and the touch interlayer insulating layer 184 may be formed of the single layer or multiple layers made of silicon nitride (SiNx) or silicon oxide (SiOx). However, the present invention is not limited thereto. For example, the touch buffer layer 181 may be formed of the single layer or the multiple layers made of silicon nitride (SiNx) or silicon oxide (SiOx), and the touch interlayer insulating layer 184 may be made of the organic layer including the organic material.

A touch planarization layer 188 may be disposed on the touch interlayer insulating layer 184 and the touch sensor metal TS. The touch planarization layer 188 may planarize the upper portion of the touch interlayer insulating layer 184. For example, the touch planarization layer 188 may be made of the organic material such as an acrylic resin, an epoxy resin, a phenolic resin, a polyamide resin, or a polyimide resin. The touch electrode TE may be formed in a mesh shape.

Although not shown, a polarizing layer may be disposed on the touch sensitive unit.

The polarizing layer prevents the reflection of the external light on the display area AA of the substrate 101. When the display apparatus 100 is used externally, the external natural light may be reflected by the reflective layer included in the anode electrode 151 or the metal electrode positioned under the light emitting device 150. The image of the display apparatus 100 may not be recognized due to the reflected light. The polarizing layer polarizes the light incident from the outside in a specific direction, so that the incident light cannot output to the outside of the display apparatus 100.

Although not shown in figure, a cover glass may be adhered to the polarizing layer by an adhesive layer. The adhesive layer adheres each component of the display apparatus 100 to each other, and may be made of an optically transparent adhesive such as a pressure sensitive adhesive, an optical clear adhesive (OCR), or an optical clear resin (OCR), but is not limited thereto.

The cover glass can protect the components of the display apparatus 100 from external impact and prevent the damage such as scratches.

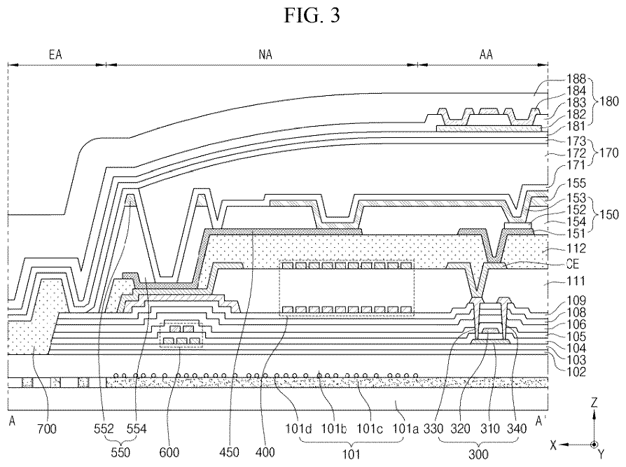

FIG. 3 is a cross-sectional view taken along line A-A′ shown in FIG. 1.

FIG. 3 illustrates the left area of the display apparatus 100 of FIG. 1, the embodiments of this specification can be equally applied to the upper and right areas of the display apparatus 100 in the same plane. Further, FIG. 3 is a drawing in which a part of the structure in the cross-sectional view of the display apparatus AA shown in FIG. 2 extends to the non-display area NA. Therefore, the structure already described in FIG. 2 will be omitted.

Referring to FIG. 3, the gate driving unit 400 may be disposed in the non-display area NA. In the embodiment according to the present specification, the gate driving unit 400 includes the same layer as the source electrode 330, the drain electrode 340, or the connection electrode CE, but is not limited thereto. For example, the gate driving unit 400 may include the same layer as the gate electrode 320.

A dam 550 may be disposed apart from the gate driving unit 400 over the light emitting device 150 to block the flow of the encapsulation material of the encapsulation unit 170 into the outside of the display apparatus 100. The dam 550 may include at least one of a lower dam 554 made of the same material as the bank 154 and an upper dam 552 made of the same material as the spacer 155. For example, the dam 550 may be formed in the stacked two layer structure by forming the bank 154 and the spacer 155 and then patterning thereof.

The bank 154 may be made of the transparent material or the opaque material for preventing the light interference between adjacent sub-pixels. For example, the bank 154 may include at least one of the organic black and the carbon, and may include the light blocking material.

The bank 154 may be formed in the entire area of the display area AA and the non-display area NA. The bank 154 may not be formed in the partial area at the end portion of the non-display area NA where the light emitting layer 152 and the dam 550 are not formed.

The spacer 155 may be disposed on the bank 154. The fine metal mask (FMM), which is a deposition mask, may be used to form the light emitting layer 152. The spacer 155 made of one of transparent organic materials, polyimide (PI), photoacrylic (PAC), and benzocyclobutene (BCB) is disposed on the bank 154 to prevent damage caused by contact between the bank 154 and the deposition mask thereon and to maintain a constant distance between the bank 154 and the deposition mask.

The crack detection unit 600 may be disposed in the area overlapping with the dam 550. The crack detection unit 600 is formed continuously along the outer portion of the display apparatus 100 to detect the cracks in the display apparatus 100.

The non-display area NA may include an outermost area EA. For example, the substrate 101 may include the display area AA and non-display area NA including the outermost area EA.

The outermost area EA may include a portion of the insulating layer and a structure 700. The structure 700 may be disposed to cover the ends of the portion of the insulating layer. The structure 700 may be formed of the same material as the second planarization layer 112 and in the same layer. The ends of the portion of the insulating layer are vulnerable to the external impact so that the crack may be generated in the insulating layer by the external impact. By covering the ends of the portion of the insulating layer with the structure 700, cracks can be prevented.

The structure 700 may be formed on the substrate 101, so that the structure 700 may not cover the substrate 101. For example, the end of the substrate 101 may be exposed.

The substrate 101 may include the first substrate 101a, the second substrate 101b, and the intermediate insulating layer 101c. The intermediate insulating layer 101c may be made of the inorganic material including silicon oxide (SiOx). The intermediate insulating layer 101c may attract moisture during the process of depositing silicon oxide (SiOx), thereby causing defects in the substrate 101.

Film peeling may generate in the intermediate insulating layer 101c in the outermost area EA or bending area BA of the substrate 101. For example, in the outermost area EA or bending area BA, the intermediate insulating layer 101c may absorb moisture, causing film peeling. The film peeling in the intermediate insulating layer 101c may be transmitted to the display area AA, causing the defect in the display apparatus 100.

According to embodiments of the present specification, a structure capable of preventing and reinforcing the film peeling from the substrate 101 can be provided. For example, the substrate 101 may include a coating layer 101d. The coating layer 101d may include a hydrophobic material. For example, the hydrophobic material may be the polymer material having a low surface energy equal to or less than a predetermined value. For example, the surface energy of the hydrophobic material may be approximately 30 mN/m or less. For example, the hydrophobic material having the low surface energy may include at least one of a fluorinated hydrophobic material, a silicone-based hydrophobic material, and a saturated alkyl hydrophobic material. The fluorinated hydrophobic material may include at least one of perfluoropolyether (PEPE) and fluoroolefin-based fluoroelastomers. The silicone-based hydrophobic material may include polydimethylsiloxane (PDMS). The saturated alkyl hydrophobic material may include at least one of polytetramethylene oxide, polyethylene oxide, polyoxetanes, polyisoprene, and polybutadiene.

Since the coating layer 101d includes the hydrophobic material, the film peeling of the intermediate insulating layer 101c can be minimized. For example, as the coating layer 101d is formed in the intermediate insulating layer 101c, the adhesive strength between the first substrate 101a and the second substrate 101b can be increased.

The coating layer 101d may be formed in an isolated form. For example, the coating layer 101d may be formed in an island form. As the coating layer 101d is formed in the isolated form, the coating layer 101d may be widely contacted with the first substrate 101a, the second substrate 101b, or the intermediate insulating layer 101c.

The coating layer 101d may be formed in the outermost area EA and the bending area BA of the substrate 101. For example, the coating layer 101d may be formed in the outer area vulnerable to moisture penetration.

According to embodiments according to the present specification, the substrate 101 may include the first substrate 101a, the second substrate 101b, and the intermediate insulating layer 101c in the display area AA of the display apparatus 100. The insulating layers related to various transistors may be deposited on the substrate 101 in the display area AA of the substrate 101, the display apparatus can have strong moisture resistant characteristics.

The coating layer 101d may not be formed in the partial area of the display area AA of the substrate 101. For example, since an optical sensor such as a proximity sensor is disposed below the substrate 101, the coating layer 101d may not be formed in the area where the optical sensor is disposed.

According to embodiments of the present specification the substrate 101 may be formed of the first substrate 101a, the second substrate 101b, the intermediate insulating layer 101c, and the coating layer 101d in the non-display area NA of the display apparatus 100. The coating layer 101d may be formed on the intermediate insulating layer 101c. The coating layer 101d may be formed in the isolated form.

According to embodiments of the present disclosure, the substrate 101 may be formed of the first substrate 101a, the second substrate 101b, and the intermediate insulating layer 101c in the outermost area EA of the display apparatus 100. The intermediate insulating layer 101c may be made of the inorganic material, such as silicon oxide (SiOx). In the outermost area EA, the display apparatus 100 can be easily damaged by the external impact. For example, the edge of the substrate 101 may be exposed in the outermost region EA. In the outermost area EA, the intermediate insulating layer 101c may be a path for propagating the crack.

According to embodiments of the present disclosure, the intermediate insulating layer 101c of the substrate 101 may be patterned. For example, the intermediate insulating layer 101c may be disposed to be spaced apart from each other by predetermined intervals, so that the propagation of the crack along the intermediate insulating layer 101c may be delayed.

In FIG. 3, the coating layer 101d is not disposed on the intermediate insulating layer 101c, but the embodiments of the present disclosure are not limited thereto. For example, the coating layer 101d may be disposed on the intermediate insulating layer 101c in the outermost area EA. The intermediate insulating layer 101c and the coating layer 101d may be patterned. For example, the intermediate insulating layer 101c and the coating layer 101d may be disposed to be spaced apart from each other by predetermined interval. The coating layer 101d may be formed in the isolated form.

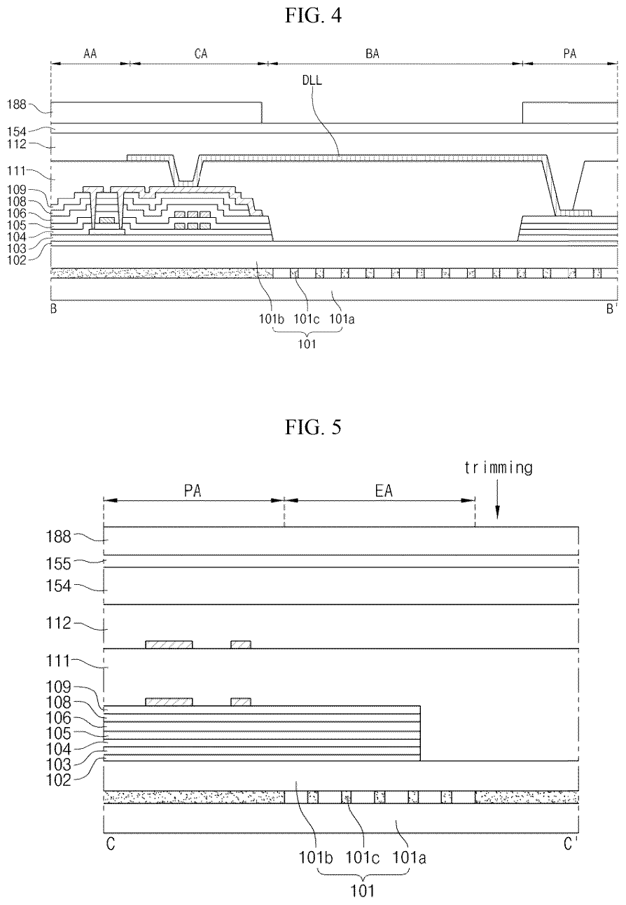

FIG. 4 is the cross-sectional view taken along line B-B′ shown in FIG. 1.

Referring to FIG. 4, the substrate 101 can be disposed across the display area AA, the connection area CA, the bending area BA, and the pad area PA.

Looking at the cross-sectional structure for each region, the first lower buffer layer 102, the first upper buffer layer 103, the first gate insulating layer 104, the first interlayer insulating layer 105, the second buffer layer 106, the second gate insulating layer 108, and the second interlayer insulating layer 109 can be formed on the substrate 101 in the display area AA.

Since the features of the display area AA shown in FIG. 4 are similar to the features of the display area AA shown in FIG. 3, the detailed description of the display area AA is omitted.

In the connection area CA, the first lower buffer layer 102, the first upper buffer layer 103, the first gate insulating layer 104, the first interlayer insulating layer 105, the second buffer layer 106, the second gate insulating layer 108, and the second interlayer insulating layer 109 can be formed on the substrate 101.

The connection area CA may be included in the non-display area NA. Various signal lines extending from the display area AA are connected in the connection area CA. For example, data link lines DLL and voltage line may be disposed in the connection area CA. The data link lines DLL may be connected to various terminals disposed in the connection area CA.

In the connection area CA, the substrate 101 may include the first substrate 101a, the second substrate 101b, the intermediate insulating layer 101c, and the coating layer 101d. The connection area CA is the area where the light emitting device is not disposed, and the coating layer 101d made of the hydrophobic material may be disposed in the connection area CA.

The bending area BA may be included in the non-display area NA. The bending area BA may be bent toward the rear side of the display area AA. The bending area BA may be the area where the link lines, such as data link lines DLL, are arranged.

The bending area BA may be the area where bending stress is concentrated. In the bending area BA, the first lower buffer layer 102, the first upper buffer layer 103, the first gate insulating layer 104, the first interlayer insulating layer 105, the second buffer layer 106, the second gate insulating layer 108, and the second interlayer insulating layer 109, which are disposed in the display area AA, may not be disposed. The first lower buffer layer 102, the first upper buffer layer 103, the first gate insulating layer 104, the first interlayer insulating layer 105, the second buffer layer 106, the second gate insulating layer 108, and the second interlayer insulating layer 109 are made of the inorganic materials, so that these layers can be broken easily by the concentrated bending stress. To prevent this breakage of the layers, the inorganic insulating material may be removed from the bending area BA. Accordingly, the first planarization layer 111 may be disposed on the substrate 101, and at this time the first planarization layer 111 may be directly contacted with the substrate 101.

In the bending area BA, the substrate 101 may include the first substrate 101a, the second substrate 101b, and the intermediate insulating layer 101c. The intermediate insulating layer 101c may be made of the inorganic insulating material, such as silicon oxide (SiOx). As described above, since the stress may be concentrated in the bending area BA, the inorganic insulating material may be removed in the substrate 101.

According to embodiments of the present specification, the intermediate insulating layer 101c may be removed from the partial area of the bending area BA. For example, the intermediate insulating layer 101c may be patterned in the bending area BA. In this case, the intermediate insulating layer is patterned in the form of a line in a direction perpendicular to the bending direction. By removing the intermediate insulating layer 101c from the partial area of the bending area BA, the substrate 101 may have the structure more robust to bending stress.

The tensile force is also applied to the connection area CA adjacent to the bending area BA as the bending area BA is bent, so that bending stress may be concentrated in the connection area CA. Therefore, in the connection area CA, the substrate 101 may include the first substrate 101a, the second substrate 101b, the intermediate insulating layer 101c, and the coating layer 101d, but is not limited thereto. For example, in the connection area CA, the substrate 101 may include the first substrate 101a, the second substrate 101b, and the intermediate insulating layer 101c, and the intermediate insulating layer 101c may be patterned. For example, the intermediate insulating layer 101c may be removed from the partial area of the connection area CA.

The pad area PA may be the area where the pad unit is disposed. The pad unit may include the data pad connected to the data terminal and the touch pad connected to the touch terminal.

In the pad area PA, the substrate 101 may include the first substrate 101a, the second substrate 101b, and the intermediate insulating layer 101c. The intermediate insulating layer 101c may be made of the inorganic insulating material such as silicon oxide (SiOx).

The end of the substrate 101 may be disposed in the pad area PA. The end of the substrate 101 may be easily exposed to the external impact. When the external impact is applied to the end of the substrate 101, the crack may be propagated from the end of the substrate 101 to the display area AA. For example, the crack may be propagated through the intermediate insulating layer 101c of the substrate 101.

According to embodiments of the present specification, the intermediate insulating layer 101c may be removed from the partial area of the pad area PA. For example, the intermediate insulating layer 101c may be patterned in the partial area of the pad area PA. As the intermediate insulating layer 101c is patterned to be disposed spaced apart from each other in the partial area of the pad area PA, the propagation of cracks from the outermost area of the substrate 101 may be delayed. According to FIG. 4, in the pad area PA, the substrate 101 includes the first substrate 101a, the second substrate 101b, and the intermediate insulating layer 101c, but is not limited thereto. For example, in the pad area PA, the substrate 101 may include the first substrate 101a, the second substrate 101b, the intermediate insulating layer 101c, and the coating layer 101d. In the display apparatus according to embodiments of the present specification, as the coating layer 101d is disposed on the intermediate insulating layer 101c in the pad area PA, the moisture penetration may be delayed from the outside.

FIG. 5 is the cross-sectional view taken along the line C-C′ shown in FIG. 1.

Referring to FIG. 5, a plurality of signal lines connected to the pad unit may be disposed on the substrate 101 in the pad area PA. The plurality of signal lines may be disposed on the first lower buffer layer 102, the first upper buffer layer 103, the first gate insulating layer 104, the first interlayer insulating layer 105, the second buffer layer 106, the second gate insulating layer 108, and the second interlayer insulating layer 109. The plurality of signal lines may be formed of the same layer as any one of the first connection electrode CE1 and the second connection electrode CE2 shown in FIG. 2, but are not limited thereto.

In the region in which the plurality of signal lines are disposed, the substrate 101 may include the first substrate 101a, the second substrate 101b, the intermediate insulating layer 101c, and the coating layer 101d.

The plurality of signal lines are not disposed in the outermost area EA. The first lower buffer layer 102, The first upper buffer layer 103, the first gate insulating layer 104, the first interlayer insulating layer 105, the second buffer layer 106, the second gate insulating layer 108, and the second interlayer insulating layer 109 may be not formed in the outermost area EA.

In the outermost area EA, the substrate 101 may include the first substrate 101a, the second substrate 101b, and the intermediate insulating layer 101c. The intermediate insulating layer 101c may be removed in the partial area of the outermost area EA. For example, the intermediate insulating layer 101c may be patterned in the partial area of the outermost area EA. In FIG. 5, the substrate 101 includes the first substrate 101a, the second substrate 101b, and the intermediate insulating layer 101c, but is not limited thereto. For example, the substrate 101 may include the first substrate 101a, the second substrate 101b, the intermediate insulating layer 101c, and the coating layer 101d. Even when the coating layer 101d is disposed on the intermediate insulating layer 101c, the intermediate insulating layer 101c may be patterned. For example, the intermediate insulating layer 101c and the coating layer 101d may be patterned.

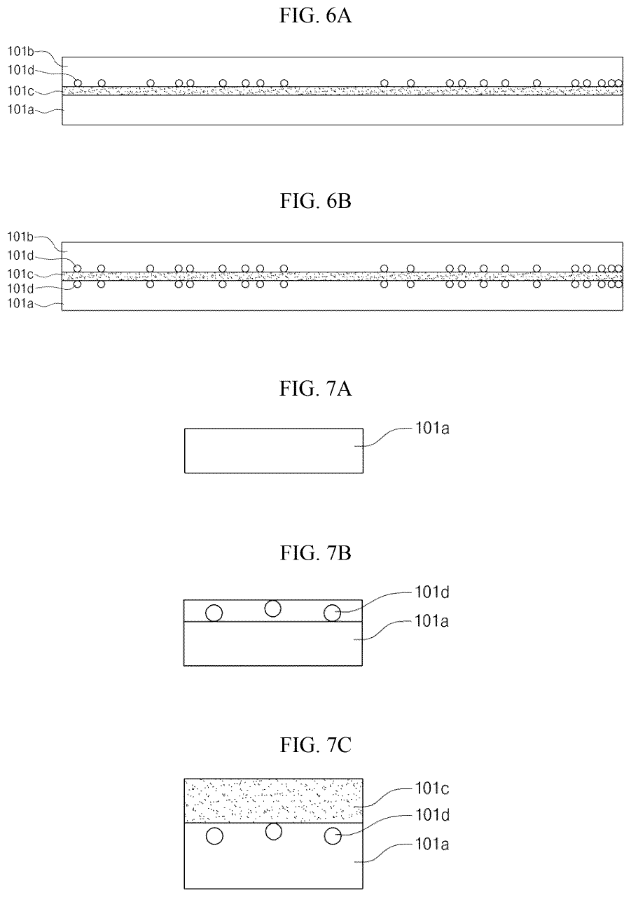

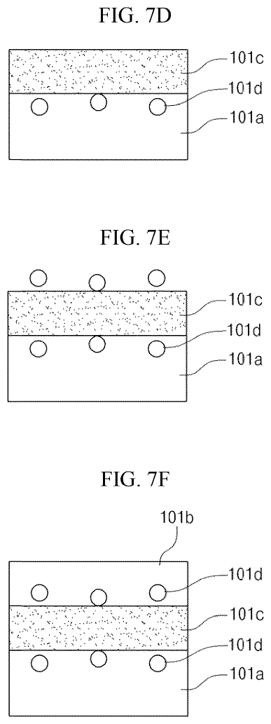

FIGS. 6A and 6B are views illustrating another embodiment of the present specification, and FIG. 7 is the view illustrating a process of forming another embodiment of the present specification.

As illustrated in FIG. 6A, the substrate 101 may include the first substrate 101a, the intermediate insulating layer 101c on the first substrate 101a, the coating layer 101d on the intermediate insulating layer 101c, and the second substrate 101b on the coating layer 101d. However, the present invention is not limited thereto. As shown in FIG. 6B, the substrate 101 may include at least one coating layer 101d. The substrate 101 may include the first substrate 101a, the coating layer 101d on the first substrate 101a, the intermediate insulating layer 101c on the coating layer 101d, the coating layer 101d on the intermediate insulating layer 101c, and the second substrate 101b on the coating layer 101d. As shown in FIG. 6B, the process for forming the coating layer 101d with the intermediate insulating layer 101c interposed therebetween will be described later.

The process of forming the substrate 101 in the display apparatus according to embodiments of the present specification is as follows. First, the first substrate 101a may be provided. (FIG. 7A) The first substrate 101a may include the organic material. After the first substrate 101a is formed, the coating layer 101d may be formed (FIG. 7B). The coating layer 101d may include the hydrophobic material. After the coating layer 101d is formed, the upper surface of the first substrate 101a may be planarized using the same material as the first substrate 101a (FIG. 7C). After the first substrate 101a and the coating layer 101d are formed, the intermediate insulating layer 101c may be formed (FIG. 7D). The intermediate insulating layer 101c may include the inorganic material. Each of the coating layer 101d and the intermediate insulating layer 101c may have a thickness less than that of the first substrate 101a. After the intermediate insulating layer 101c is formed, the coating layer 101d may be formed on the intermediate insulating layer 101c (FIG. 7E). The coating layer 101d formed in FIG. 7E may be formed of the same material as the coating layer 101d formed in FIG. 7B, and may have the same thickness. After the coating layer 101d is formed, the second substrate 101b may be formed (FIG. 7F). The second substrate 101b may include the organic material. The first substrate 101a and the second substrate 101b may be formed of the same material. The second substrate 101b may have the thickness greater than that of the first substrate 101a.

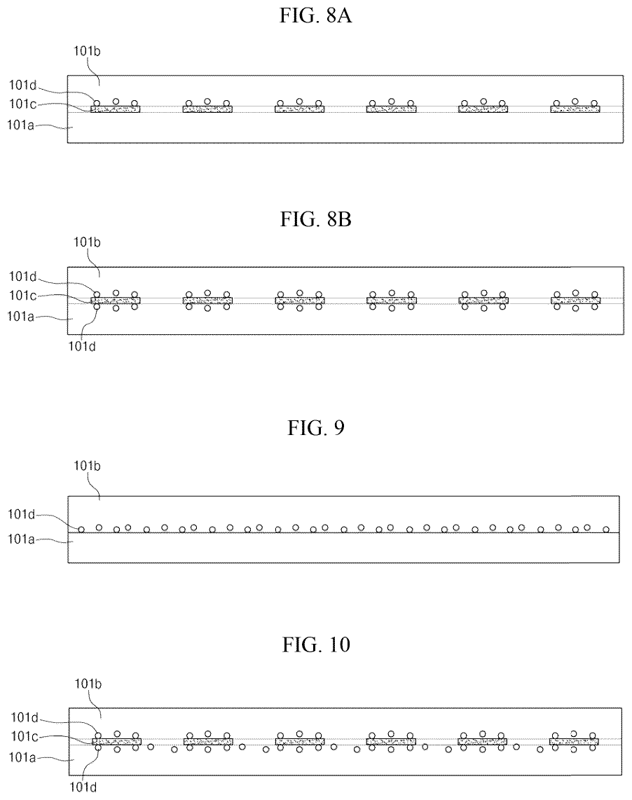

FIGS. 8A, 8B, 9, and 10 are views showing another embodiment of the present specification.

As shown in FIG. 8A and FIG. 8B, the display apparatus according to embodiments of the present specification may include the patterned intermediate insulating layer 101c. For example, the intermediate insulating layer 101c may be formed in a line shape. The coating layer 101d may be formed in the same shape as the patterned intermediate insulating layer 101c. For example, the coating layer 101d may be formed on the intermediate insulating layer 101c, and the plurality of coating layers 101d may be formed with the intermediate insulating layer 101c interposed therebetween.

As illustrated in FIG. 9, the display apparatus according to embodiments of the present specification may include the first substrate 101a, the second substrate 101b, and the coating layer 101d in the region in which the intermediate insulating layer 101c is not formed. For example, the substrate 101 may be formed of the first substrate 101a, the second substrate 101b, and the coating layer 101d.

As illustrated in FIG. 10, the display apparatus in accordance with the embodiments of the present specification may include both the coating layer 101d shown in FIGS. 8A and 8B and the coating layer 101d shown in FIG. 9. For example, the substrate 101 may include the patterned intermediate insulating layer 101c. The plurality of coating layers 101d may be disposed with the patterned intermediate insulating layer 101c interposed therebetween. The coating layer 101d disposed on the intermediate insulating layer 101c may be formed to correspond to the patterned shape of the intermediate insulating layer 101c, and the coating layer 101d disposed under the intermediate insulating layer 101c may be formed in the entire area including the area in which the intermediate insulating layer 101c is patterned.

Meanwhile, in the present specification, the intermediate insulating layer of the non-display area is patterned to reduce crack propagation and stress. Since the density of some regions becomes smaller than that of other regions by the patterning, the propagation of cracks may be blocked and the applied stress may be absorbed. By patterning the intermediate insulating layer, the density of this region may be minimized to minimize crack propagation and maximize stress absorption.

Accordingly, the present specification is not limited to the structure in which a portion of the intermediate insulating layer of the non-display area is patterned, but may also be applied to various structure in which the density of the non-display area is smaller than that of other areas. The same effect may be obtained in this structure. In this case, the region having different densities of the non-display area may be formed of the same material having different densities or may be formed a plurality of regions having different densities.

The display apparatus according to the embodiments of the present specification may be described as follows.

The display apparatus according to embodiments of the present specification includes the substrate including the display area and the non-display area, the thin film transistor on the substrate, the light emitting device over the thin film transistor, wherein the substrate includes the first substrate, the second substrate on the first substrate, the intermediate insulating layer between the first substrate and the second substrate, and the intermediate insulating layer in the display area and the intermediate insulating layer in the non-display area may have different shapes.

According to one or more embodiments of the present specification, the non-display area includes a bezel area adjacent to the display area, a pad area disposed to be spaced apart from the display area, and a bending area between the bezel area and the pad area.

According to one or more embodiments of the present specification, the bezel area may include the outermost area, and the intermediate insulating layer may be patterned in the outermost area.

According to one or more embodiments of the present specification, the coating layer made the hydrophobic material is disposed on the intermediate insulating layer.

According to one or more embodiments of the present specification, the coating layer is made of at least one material selected from the group consisting of a fluorine-based hydrophobic material, a silicon-based hydrophobic material, and a saturated alkyl-based hydrophobic material.

According to one or more embodiments of the present specification, the shape of the coating layer corresponds to a patterned shape of the intermediate insulating layer.

According to one or more embodiments of the present specification, the display apparatus further comprises the coating layer formed on at least one of the first surface of the intermediate insulating layer facing the first substrate and the second surface of the intermediate insulating layer facing the second substrate, the coating layer being made of a hydrophobic material.

According to one or more embodiments of the present specification, at least a part of the plurality of areas of the intermediate insulating layer is patterned in the bending area.

According to one or more embodiments of the present specification, the intermediate insulating layer is patterned in the form of a line in a direction perpendicular to the bending direction.

According to one or more embodiments of the present specification, the planarization layer is disposed over the thin film transistor in the bending area and the planarization layer is directly contacted with the substrate.

The above description and the accompanying drawings are merely illustrative of the technical spirit of the present disclosure, and those of ordinary skill in the art to which the present disclosure pertains can combine configurations within a range that does not depart from the essential characteristics of the present disclosure, various modifications or variations such as separation, substitution and alteration will be possible. Therefore, the embodiments disclosed in the present disclosure are not intended to limit the technical spirit of the present disclosure, but to explain, and the scope of the technical spirit of the present disclosure is not limited by these embodiments.

What is claimed is:

1. A display apparatus, comprising:
a substrate including a display area and non-display area;
a thin film transistor over the substrate; and
a light emitting device over the thin film transistor,
wherein the substrate includes a first substrate, a second substrate on the first substrate, and an intermediate insulating layer between the first substrate and the second substrate,
wherein the intermediate insulating layer in the display area has a same density, and
wherein the intermediate insulating layer in the non-display area includes a plurality of areas having different densities.

2. The display apparatus of claim 1, wherein at least a partial region of the plurality of areas of the interlayer insulating layer in the non-display area is patterned.

3. The display apparatus of claim 2, wherein the non-display area includes a bezel area adjacent to the display area, a pad area spaced apart from the display area, and a bending area between the bezel area and the pad area.

4. The display apparatus of claim 3, further comprising a coating layer formed on at least one of a first surface of the intermediate insulating layer facing the first substrate and a second surface of the intermediate insulating layer facing the second substrate, the coating layer made of a hydrophobic material.

5. The display apparatus of claim 4, wherein the coating layer is made of at least one material selected from the group consisting of a fluorine-based hydrophobic material, a silicon-based hydrophobic material, and a saturated alkyl-based hydrophobic material.

6. The display apparatus of claim 4, wherein a shape of the coating layer corresponds to a patterned shape of the intermediate insulating layer.

7. The display apparatus of claim 3, wherein at least a part of the plurality of areas of the intermediate insulating layer is patterned in the bending area.

8. The display apparatus of claim 7, wherein the intermediate insulating layer is patterned in the form of a line in a direction intersecting the bending direction.

9. The display apparatus of claim 3, further comprising a planarization layer over the thin film transistor in the bending area,
wherein the planarization layer is in direct contact with the substrate.

10. The display apparatus of claim 7, further comprising a coating layer formed on at least one of a first surface of the intermediate insulating layer facing the first substrate and a second surface of the intermediate insulating layer facing the second substrate in the bending area, the coating layer made of a hydrophobic material.

11. The display apparatus of claim 10, wherein the coating layer is made of at least one material selected from the group consisting of a fluorine-based hydrophobic material, a silicon-based hydrophobic material, and a saturated alkyl-based hydrophobic material.

12. The display apparatus of claim 10, wherein a shape of the coating layer corresponds to a patterned shape of the intermediate insulating layer.
